(19) United States
(12) Patent Application Publication
(10) Pub. No.: US 2026/0372105 A1
(43) Pub. Date: Nov. 19, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Leu-Jen Chen, Taipei (TW); Wen-Wei Shen, Hsinchu (TW); Kuan-Yu Huang, Taipei (TW); Yu-Shun Lin, Taipei City (TW); Sung-Hui Huang, Yilan County (TW); Hsien-Pin Hu, Hsinchu County (TW); Shang-Yun Hou, Hsinchu (TW)

(73) Assignee: Taiwan Semiconductor Manufacturing Company, Ltd., Hsinchu (TW)

(21) Appl. No.: 19/754,249

(22) Filed: Jul. 26, 2026

Related U.S. Application Data
(62) Division of application No. 18/474,259, filed on Sep. 26, 2023.

(51) Int. Cl. H10W 42/00; H10W 72/00; H10W 72/20; H10W 72/90; H10W 74/01; H10W 74/15; H10W 90/00

(52) U.S. Cl. CPC H10W 42/121; H10W 42/00; H10W 74/012; H10W 74/15; H10W 72/072; H10W 72/07236; H10W 72/073; H10W 72/248; H10W 72/263; H10W 72/267; H10W 72/967; H10W 90/724; H10W 90/734

(57) ABSTRACT

A semiconductor package includes a semiconductor die, an interposer disposed below the semiconductor die, first joints electrically coupling the semiconductor die to the interposer, at least one second joint coupling the semiconductor die to the interposer, and a first underfill disposed between the semiconductor die and the interposer to surround the active and second joints. The semiconductor die includes a first region, a seal ring region surrounding the first region, and a second region between the seal ring region and a die edge. The first joints are located within the first region, and the second joint is disposed at a die corner within the second region and is electrically floating in the semiconductor package.

### CROSS-REFERENCE TO RELATED APPLICATION

This application is a divisional application of and claims the priority benefit of a prior application Ser. No. 18/474,259, filed on Sep. 26, 2023. The entirety of the above-mentioned patent application is hereby incorporated by reference herein and made a part of this specification.

### BACKGROUND

Semiconductor devices and integrated circuits used in a variety of electronic applications are typically manufactured from a semiconductor wafer. The semiconductor dies of the semiconductor wafer are processed and packaged with other electronic devices at the wafer level, and various technologies have been developed for wafer level packaging. Although existing semiconductor package and manufacturing method thereof have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic cross-sectional view of a semiconductor die, in accordance with some embodiments.

FIG. 1B illustrates a schematic plan view of a semiconductor die, in accordance with some embodiments.

FIGS. 2A through 2D illustrate schematic cross-sectional views of intermediate steps during a process for forming a semiconductor package, in accordance with some embodiments.

FIGS. 3A through 3C illustrate schematic enlarged views of some other embodiments of the structure in the dashed box B outlined in FIG. 2D.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A flip chip assembly includes a direct electrical connection of a die onto a circuit carrier (e.g., interposer) using conductive bumps (e.g., solder bumps). For example, the flip chip assembly is made by attaching the conductive bumps of the die to the circuit carrier and applying an underfill between the die and the circuit carrier. The underfill between the die and the circuit carrier is used to increase the reliability of the resulting structure by reducing stresses on the conductive bumps. During various processes, there are many mechanical and/or thermal stresses exerted on the die. Unfortunately, especially for a large-scale package, the underfill at the die edge is prone to cracking/delamination caused by stresses. Such defects (e.g., cracking/delamination) impact the reliability of the resulting structure. These and other problems may be solved, and technical advantages are achieved, by the embodiments of the present disclosure, in which a dummy pad (or defect prevention) structure including dummy bumps/pads is formed in proximate to the die corner/edge outside the seal ring structure.

Embodiments will be described with respect to embodiments in a specific context, namely a dummy pad structure of a semiconductor package, and a method of forming the same. Aspects of the embodiments may be applied to a dummy pad structure which may advantageously anchor the underfill, which may thereby protect the underfill at the die edge from cracking/delamination, and which may also provide improved stress relief, without having a significant impact on manufacture processes, time and costs. In addition, roughening a portion of the passivation layer near the die edge/corner will enhance the adhesion between the die and the underfill. Various embodiments presented herein allow for reducing a stress on the underfill at the die edge/corner, reducing or eliminating the generation of defects in the underfill due to the stress, and improving the reliability of the semiconductor package.

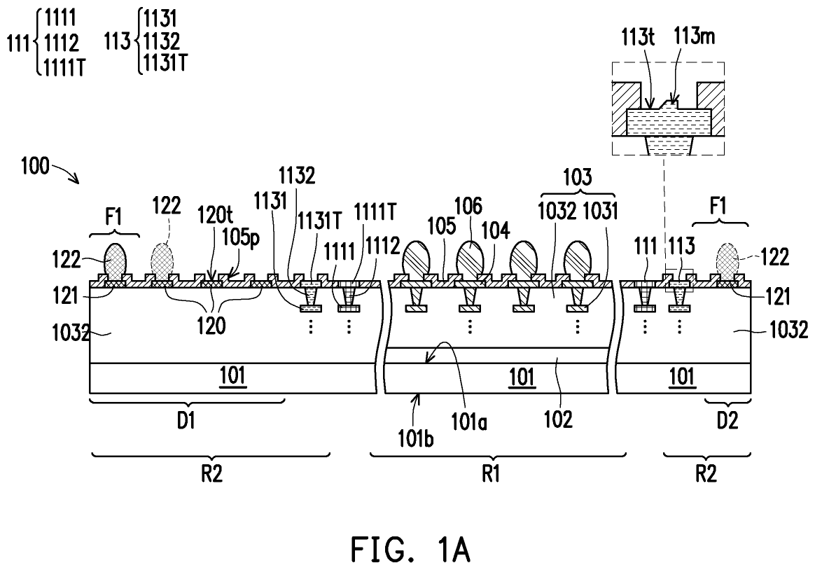

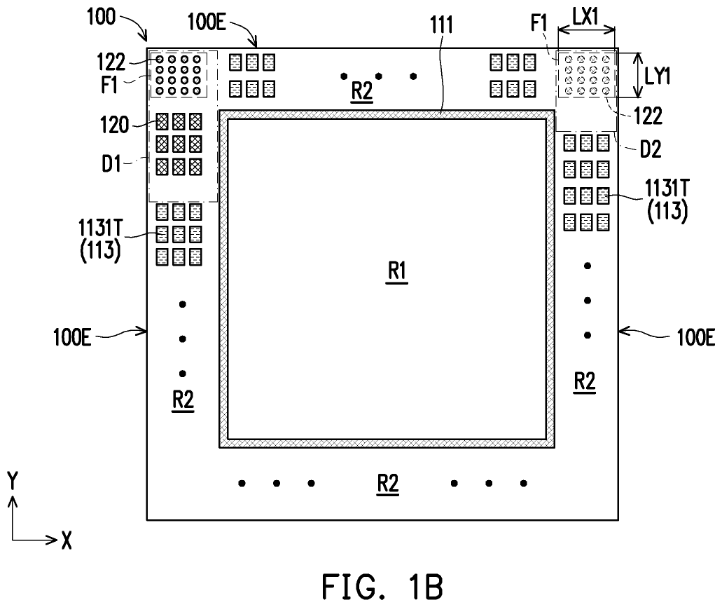

FIG. 1A illustrates a schematic cross-sectional view of a semiconductor die 100 and FIG. 1B illustrates a schematic plan view of the semiconductor die 100, in accordance with some embodiments. It should be noted that FIG. 1B is simplified for clarity, and FIG. 1B may not depict all of the components of the semiconductor die 100. For example, the active bumps in the first region and the passivation layer across the semiconductor die are not illustrated in FIG. 1B.

Referring to FIG. 1A, the semiconductor die 100 is provided. The semiconductor die 100 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The semiconductor die 100 may be formed in a semiconductor wafer, which may include different die regions that are singulated in subsequent steps to form a plurality of semiconductor dies 100. The semiconductor die 100 may be processed according to applicable manufacturing processes to form integrated circuits. In some embodiments, the semiconductor die 100 includes a semiconductor substrate 101, such as silicon, doped or undoped, or an active layer of a semiconductor-on-insulator (SOI) substrate. The semiconductor substrate 101 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may be used, according to some other embodiments. The semiconductor substrate 101 may have an active surface (or a front side) 101a, and a rear surface (or a back side) 101b opposite to the active surface 101a.

In some embodiments, the semiconductor die 100 includes a device layer 102 formed in/on the active surface 101a of the semiconductor substrate 101. The device layer 102 may include a plurality of active/passive devices (not individually shown; e.g., transistors, diodes, capacitors, resistors, and/or the like). The device layer 102 may be formed through front-end-of-line (FEOL) processes and may be referred to as a FEOL layer. The device layer 102 may include an inter-layer dielectric (ILD) layer (not shown) formed on the active surface 101a of the semiconductor substrate 101 and surrounding the devices. The ILD layer may include one or more dielectric materials such as Phospho-Silicate Glass (PSG), Boro-Silicate Glass (BSG), Boron-Doped Phospho-Silicate Glass (BPSG), undoped Silicate Glass (USG), the like, or combinations thereof. The device layer 102 may include conductive plugs (not shown) extending through the ILD layer to be electrically and physically coupled to the devices. In some embodiments where the devices are transistors, the conductive plugs may be coupled to the gates and source/drain regions of the transistors.

With continued reference to FIG. 1A, the semiconductor die 100 may include an interconnect structure 103 formed on the device layer 102. The interconnect structure 103 may interconnect the devices in the device layer 102 to form an integrated circuit. The interconnect structure 103 may be formed through back-end-of-line (BEOL) processes. In some embodiments, interconnect structure 103 is formed of alternating layers of dielectric (e.g., low-k dielectric material) and conductive material (e.g., copper) with vias interconnecting the layers of conductive material and may be formed through any suitable process (such as deposition, damascene, dual damascene, or the like). For example, the interconnect structure 103 includes conductive patterns 1031 and dielectric layers 1032 covering the conductive patterns 1031. The conductive patterns 1031 may include conductive lines, conductive pads, and conductive vias, etc., and may be formed in one or more dielectric layers 1032. The conductive patterns 1031 are electrically coupled to the devices in the device layer 102 through, e.g., the conductive plugs (not individually shown).

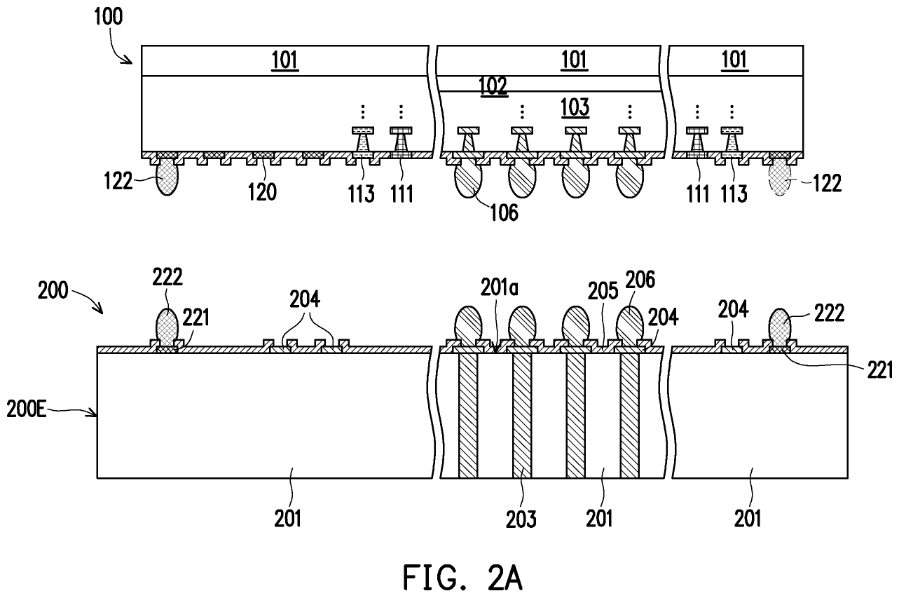

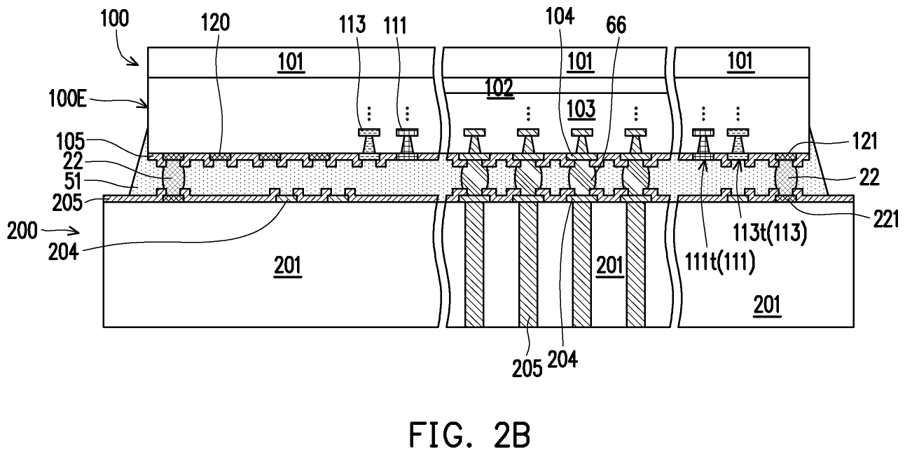

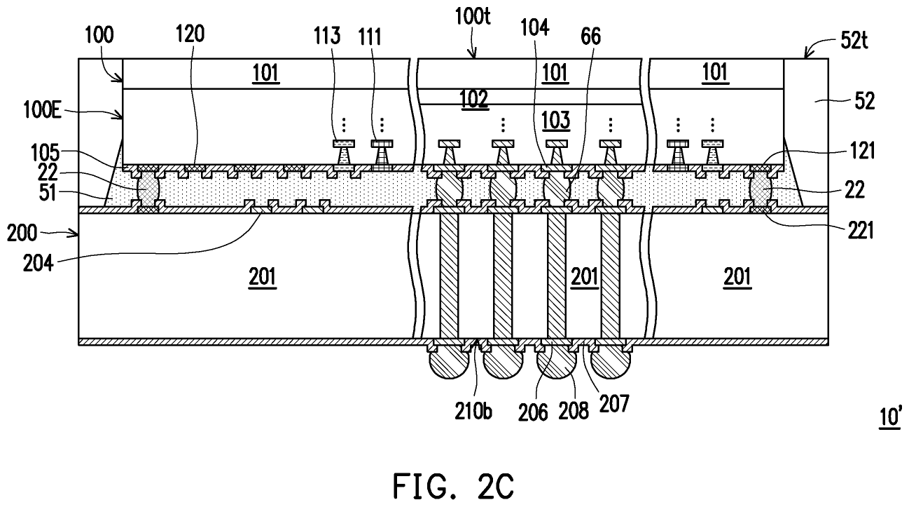

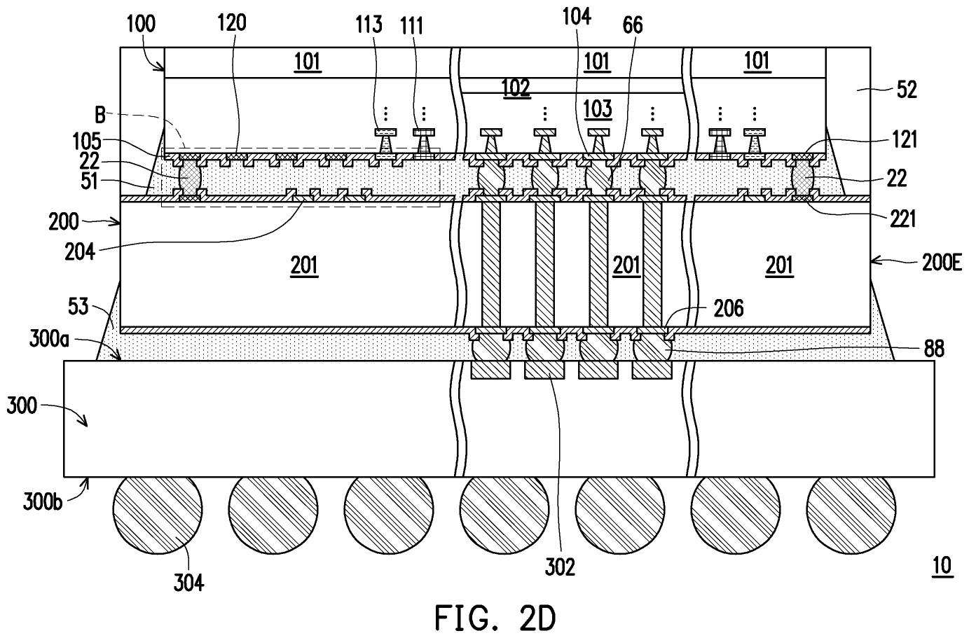

In some embodiments, the semiconductor die 100 includes contact pads 104 (e.g., aluminum pads, aluminum-copper pads, or the like) to which external connections are made. The contact pads 104 are formed over the active side of the semiconductor die 100, such as in and/or on the interconnect structure 103. In some embodiments, the semiconductor die 100 includes a passivation layer 105 formed on the interconnect structure 103 and partially covering the contact pads 104, where openings 105p extend through the passivation layer 105 to the contact pads 104. In some embodiments, the passivation layer 105 includes one or more layers of silicon oxide, silicon nitride, silicon oxynitride, the like, or a combination thereof. In some embodiments, the semiconductor die 100 includes conductive bumps 106 extending through the openings 105p of the passivation layer 105 to be physically and electrically coupled to corresponding ones of the contact pads 104. The conductive bumps 106 are electrically coupled to the respective integrated circuits of the semiconductor die 100 and may be referred to as active (or functional) bumps. The conductive bumps 106 may be or include ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, solder material is deposited over the contact pads 104, and then heated via a reflow process to form a generally spherical conductive bump 106. In some embodiments, the conductive bumps 106 are used to establish electrical contact between the semiconductor die 100 and an interposer, as will described later in accompanying with FIGS. 2A-2B.

With continued reference to FIG. 1A and referring to FIG. 1B, the semiconductor die 100 includes a first region (or an active/functional region) R1 and a second region (or an inactive/non-functional region) R2 surrounding the first region R1. In some embodiments, in the top-down view, the first region R1 is the central region of the semiconductor die 100, and the second region R2 is the peripheral region of the semiconductor die 100. For example, the device layer 102 and the overlying structure (e.g., the interconnect structure 103, the contact pads 104, and the conductive bumps 106) are disposed within the first region R1. It should be noted that the conductive bumps 106 within the first region R1 are not shown in FIG. 1B for the sake of simplicity, and the number and the configuration of the conductive bumps 106 construe no limitation in the disclosure.

In some embodiments, the semiconductor die 100 includes one or more seal ring structure 111 surrounding the perimeter of the first region R1 and located between the first region R1 and the second region R2. For example, in the plan view, the inner boundary of the seal ring structure 111 defines the outer boundary of the first region R1, and the area outside the outer boundary of the seal ring structure 111 defines the second region R2. The seal ring structure 111 may be a close loop encircling the perimeter of the first region R1 and acting a barrier to penetration of moisture and chemicals into the first region R1. For example, the seal ring structure 111 protects the devices in the device layer 102 and the interconnect structure 103 from contaminants and prevents the stacked layers of conductive patterns 1031 and dielectric layers 1032 from cracking or delaminating, such as by providing stress relief.

The seal ring structure 111 may include multiple metallic layers. In some embodiments, the seal ring structure 111 is formed at the same time as the conductive patterns 1031 and may be substantially similar in composition and fabrication to the conductive patterns 1031. For example, the seal ring structure 111 includes conductive pads 1111 and conductive vias 1112 landing on respective ones of the conductive pads 1111 and substantially spanning the height of the seal ring structure 111, where the conductive pads 1111 and the conductive vias 1112 are embedded in one or more dielectric layers 1032. In some embodiments, the topmost conductive pads 1111T of the seal ring structure 111 are located at the same level as the contact pads 104 and may be at least laterally covered by the passivation layer 105. In some embodiments, the top surfaces of the topmost conductive pads 1111T are substantially leveled (or coplanar) with the top surface of the passivation layer 105, within process variations. Alternatively, the topmost conductive pads 1111T are fully (or partially) covered by the passivation layer 105.

With continued reference to FIGS. 1A-1B, the semiconductor die 100 may include one or more test line structure 113 disposed within the second region R2 and outside the seal ring structure 111. In the plan view, the test line structure 113 may be disposed between the seal ring structure 111 and the die edge 100E. The test line structure 113 may be used to verify the properties of the semiconductor die 100 such as used in the wafer acceptance tests (WAT). For example, the test line structure 113, when initially formed, is electrically coupled to the functional circuits in the first region R1; once the semiconductor die 100 is separated from the semiconductor wafer through the singulation process, the test line structure 113 may be no longer electrically coupled to the functional circuits in the first region R1 and may be electrically floating.

In some embodiments, the test line structure 113 includes conductive pads 1131 and conductive vias 1132 landing on corresponding ones of the conductive pads 1131, where the conductive pads 1131 and conductive vias 1132 are embedded in the dielectric layers 1032. The conductive pads 1131 and the conductive vias 1132 may be fabricated simultaneously with the multilayer interconnects in the interconnect structure 103 using a method such as dual damascene processing. The topmost conductive pads, which are called test pads 1131T or WAT pads, may be formed at the same time and located at the same level as the contact pads 104. The test pads 1131T may be arranged in an array within the second region R2. The conductive pads 1131 and the conductive vias 1132 may be substantially similar in composition and fabrication to the conductive patterns 1031, and the test pads 1131T may be substantially similar in composition and fabrication to the contact pads 104. The test pads 1131T may be partially covered by the passivation layer 105. For example, at least a portion of the top surface 113t of the respective test pad 1131T is accessibly exposed by the opening 105p of the passivation layer 105. In some embodiments, a bump 113m (e.g., probe mark; shown in the enlarged view of FIG. 1A) is formed on the top surface 113t of the respective test pad 1131T as a result of the probing.

In some embodiments, the test line structure 113 may be located within the scribe line area of the semiconductor wafer, but would not be necessary for the functioning of the semiconductor die 100 once the semiconductor die 100 has been cut from the semiconductor wafer. As mentioned above, the semiconductor die 100 is formed in a semiconductor wafer including different die regions; for example, the semiconductor wafer may include a plurality of scribe line areas between adjacent die regions, and the test line structure 113 may be placed in the scribe line areas and used for tests or other functions. The scribe line areas are formed by not placing functional structures (structures that will be used by the semiconductor die 100 once it has been cut from the semiconductor wafer) into the area intended for the scribe line areas. A probe card including a plurality of probe pins (not shown) may apply test signals to and receives responses from the test line structure(s) 113 through the probe pins. The probing may result in the bump 113m (e.g., probe mark) to be generated. In the BEOL test, the test line structures 113 may ensure process stability on various parameters. Upon finishing tests, failed dies are identified and only known good dies will be used in the subsequent processes. The semiconductor wafer is then singulated by dicing along the scribe line areas, and thus the individual semiconductor dies 100 are created. In some embodiments, at least one of the test pads 1131T and the underlying structure may be left in the resulting semiconductor die 100 after the singulation process.

With continued reference to FIGS. 1A-1B, the semiconductor die 100 may include one or more dummy area (e.g., D1 and D2) disposed within the second region R2 and outside the seal ring structure 111. The dummy area (e.g., D1 and D2) may be a blank area which is free of functional structures used by the semiconductor die 100 or may be the area other than the distributed area of the test line structures 113 within the second region R2. In some embodiments, in the plan view, the dummy area (e.g., D1 or D2) is alongside the test line structures 113 along the lengthwise direction (e.g., the Y axis) of the respective test pad 1131T. For example, the dummy area (e.g., D1 or D2) is disposed between the array of the test pads 1131T and the die edge 100E. Alternatively, the dummy area is alongside the test line structures along the X axis or may be of an L shape extending along both of the X and Y axis.

An exemplary shape of the dummy area (e.g., D1 and D2) may be designed to substantially occupy in a rectangular area or a square area, although other shapes may be adopted according to various embodiments. In the illustrated embodiment, two of the dummy areas D1 and D2 are disposed at the upper left portion and the upper right portion of the semiconductor die 100 in the plan view. In some embodiments, the dummy areas (e.g., D1 and D2) have different sizes and may have the asymmetrical configuration. The configuration of the dummy areas may depend on the distribution of the test line structures 113 within the second region R2. Alternatively, one or more than two dummy areas may be disposed within the second region R2. The dummy areas may have the same size and may have the symmetrical configuration. It should be noted that the number, the shape, and the configuration of the dummy areas construe no limitation in the disclosure.

The semiconductor die 100 may include one or more forbidden zone F1 outside the seal ring structure 111 and located within the second region R2. The forbidden zone F1 may be viewed as a die corner region and may be included in the dummy area (e.g., D1 and/or D2). The functional circuits of the semiconductor die 111 may be excluded from the forbidden zone F1, since the forbidden zone F1 is a region that may undergo greater stress during/after processing (e.g., die sawing and packaging). The forbidden zone(s) F1 may be located in one or more corner(s) of the semiconductor die 100. It should be noted that two forbidden zones F1 at the upper die corners are illustrated as an example, the forbidden zones may be arranged at each die corner according to other embodiments, and thus the number of the forbidden zones F1 may be modified depending on product requirements. An exemplary shape of the forbidden zones F1 may be designed to substantially occupy in a rectangular area or a square area, at the die corner, although other shapes may also be adopted. An exemplary size of the forbidden zone F1 may have outlines (e.g., LX1 (measured along the X axis) and LY1 (measured along the Y axis)) ranging from about 60 μm to about 250 μm, such as about 155 μm. Although other values may also be adopted, depending on the design rules and specifications. In some embodiments, the forbidden zones F1 at each die corner may have a same dimension. Alternatively, the dimension of the forbidden zones F1 at the different die corners may vary; that is, the forbidden zones F1 at the die corners may have the asymmetrical configuration.

Still referring to FIGS. 1A-1B, one or more first dummy pad(s) 120 may be disposed within the dummy area (e.g., D1 and/or D2) outside the forbidden zone F1. The first dummy pads 120 may be electrically floating in the semiconductor die 100. In some embodiments, the first dummy pads 120 are of the same size and may be arranged in an array. Depending on the size of free space in the dummy area, the first dummy pads 120 may (or may not) be disposed within the dummy area. In the illustrated embodiments, the first dummy pads 120 are disposed within the dummy area D1, while the dummy area D2 is free of the first dummy pads. For example, since the size of the dummy area D2 substantially matches the size of the forbidden zone F1, there is no enough space for configuring the first dummy pads in the dummy area D2. Alternatively, the first dummy pad(s) 120 may be disposed within each of the dummy areas, as the respective dummy area is large enough to accommodate the first dummy pad(s) 120. In some embodiments, the total area of the first dummy pads 120 is greater than 15% of the overall area of the dummy area (e.g., D1) in which the first dummy pads 120 are located. It should be noted that the number, the size, the configuration of the first dummy pad(s) 120 illustrated herein are merely examples and construe no limitation in the disclosure.

The first dummy pads 120 may be formed simultaneously with the contact pads 104 in the first region R1 and may be substantially similar in composition to the contact pads 104. In some embodiments, the first dummy pads 120 are directly formed on the topmost one of the dielectric layers 1032. Alternatively, the first dummy pads 120 and the contact pads 104 may have different materials, where the material of the first dummy pads 120 may be conductive or non-conductive. The passivation layer 105 may partially cover the respective first dummy pad 120, and at least a portion of the top surface 120t of the respective first dummy pad 120 is accessibly exposed by the opening 105p of the passivation layer 105. The top surfaces 120t of the first dummy pads 120 may be smoother than the top surfaces 113t of the test pads 1131T, since the respective test pad 1131T may have the probe mark 113m after the probing. The openings 105p of the passivation layer 105 revealing the first dummy pads 120 arranged within the dummy area(s) may provide a roughened topography that facilitate the adhesion between the underfill and the semiconductor die 100 at the die corner(s) in the subsequent process, and the details thereof will be described later in accompanying with FIG. 2B.

In some embodiments, second dummy pads 121 and dummy bumps 122 formed on the second dummy pads 121 with a one-to-one correspondence may be disposed within the respective forbidden zone F1, where the second dummy pads 121 and the dummy bumps 122 are electrically floating in the semiconductor die 100. In some embodiments, the second dummy pads 121 are directly formed on the topmost one of the dielectric layers 1032 and may be partially covered by the passivation layer 105. The dummy bumps 122 may extend through the openings 105p of the passivation layer 105 to land on the second dummy pads 121. In some embodiments, the second dummy pads 121 and the dummy bumps 122 are the conductive features which are most proximate to the die edge 100E. In the plan view, the dummy bumps 122 may be arranged in an array within the forbidden zone F1. In some embodiments, in the respective dummy area (D1 or D2), the distribution area of the dummy bumps 122 is less than the distribution area of the first dummy pads 120. For example, the total area of the dummy bumps 122 may be greater than 1.64% of the overall area of the dummy area (e.g., D1 or D2) in which the dummy bumps 122 are located.

The second dummy pads 121 may be formed simultaneously with the first dummy pads 120 and may be substantially similar in composition to the first dummy pads 120. The first dummy pads 120, the second dummy pads 121, and the contact pads 104 may have the same size. Alternatively, the first and second dummy pads (120 and 121) have the size different from the contact pads 104. In one embodiment, the size of the first dummy pads 120 is different from the second dummy pads 121. In some embodiments, the second dummy pads 121 and the dummy bumps 122 are formed at the same time as the contact pads 104 and the active bumps 106, respectively. The active bumps 106 and the dummy bumps 122 may have the same size or may have different sizes. The second dummy pads 121 and the dummy bumps 122 may be substantially similar in composition and fabrication to the contact pads 104 and the active bumps 106, respectively. For example, the dummy bumps 122 are solder bumps. Alternatively, the dummy bumps are made of different material than the active bumps 106.

In some embodiments, the dummy bumps 122 are omitted and only the second dummy pads 121 are located within the forbidden zone F1; therefore, one of the dummy bumps 122 in the dummy area D2 of FIG. 1A is illustrated in the dashed line to indicate it may or may not exist. In some embodiments, at least one dummy bump 122 is disposed on the first dummy pad 120 outside the forbidden zone F1 and within the dummy area (e.g., D1); therefore, the dummy bump 122 outside the forbidden zone F1 and in the dummy area D1 of FIG. 1A is illustrated in the dashed line to indicate it may or may not exist. In some other embodiments, the dummy bumps 122 land on all of the first and second dummy pads 120 and 121. The number and the configuration of the dummy bumps 122 illustrated herein are merely examples and construe no limitation in the disclosure. The above examples are provided for illustrative purposes only, and the semiconductor die 100 may utilize fewer or additional elements, in other embodiments.

FIGS. 2A through 2D illustrate schematic cross-sectional views of intermediate steps during a process for forming a semiconductor package, in accordance with some embodiments. Although method embodiments are discussed as being performed in a particular order, other embodiments may be performed in any logical order.

Referring to FIG. 2A and with reference to FIG. 1A, the semiconductor die 100 and an interposer 200 may be provided, respectively. The semiconductor die 100 is substantially the same as the semiconductor die 100 described in FIG. 1A, and thus the details thereof are not repeated for the sake of brevity. The interposer 200 described below is an example and may be replaced with a semiconductor device, an integrated circuit die structure, an integrated circuit package, or any type of package component. The interposer 200 may be formed in a semiconductor wafer, which is singulated in subsequent steps to form a plurality of interposers 200. The interposer 200 may be processed according to applicable manufacturing processes. For example, the interposer 200 includes a semiconductor substrate 201. In some embodiments, the semiconductor substrate 201 is similar to the semiconductor substrate 101 of the semiconductor die 100 described above with reference to FIG. 1A, and the description is not repeated herein. The interposer 200 may (may not) include active and/or passive devices formed in/on the semiconductor substrate 201. In some embodiments, the interposer 200 includes through substrate vias (TSVs) 203 extending through the semiconductor substrate 201. The TSVs 203 may include a conductive material such as copper, alloy, and/or the like.

The interposer 200 may include first contact pads 204 formed on a first side 201a of the semiconductor substrate 201 and electrically coupled to the TSVs 203. In the illustrated embodiment, each first contact pad 204 is in physical and electrical contact with one of the TSVs 203. In some embodiments, the interposer 200 includes an interconnect structure (not shown) formed on the first side 201a of the semiconductor substrate 201 and interposed between the first contact pads 204 and the TSVs 203. The interposer 200 may include a first dielectric layer 205 overlying the first side 201a of the semiconductor substrate 201 and partially covering the first contact pads 204, where the openings of the first dielectric layer 205 may accessibly expose at least a portion of each first contact pads 204. The first dielectric layer 206 may be a passivation film or may include any suitable dielectric material(s) such as an oxide, a nitride, a polymer (e.g., polyimide (PI), polybenzoxazole (PBO), benzocyclobutene (BCB), etc.), or the like. In some embodiments, the interposer 200 includes first conductive bumps (or first active bumps) 206 formed on the first contact pads 204. The first conductive bumps 206 may be similar to the conductive bumps 106 of the semiconductor die 100 described above with reference to FIG. 1A, and the description is not repeated herein. In some embodiments, not every first contact pad 204 has the first conductive bump 206 formed thereon; for example, there is a portion of first contact pads 204 that do not have the first conductive bump 206 formed thereon.

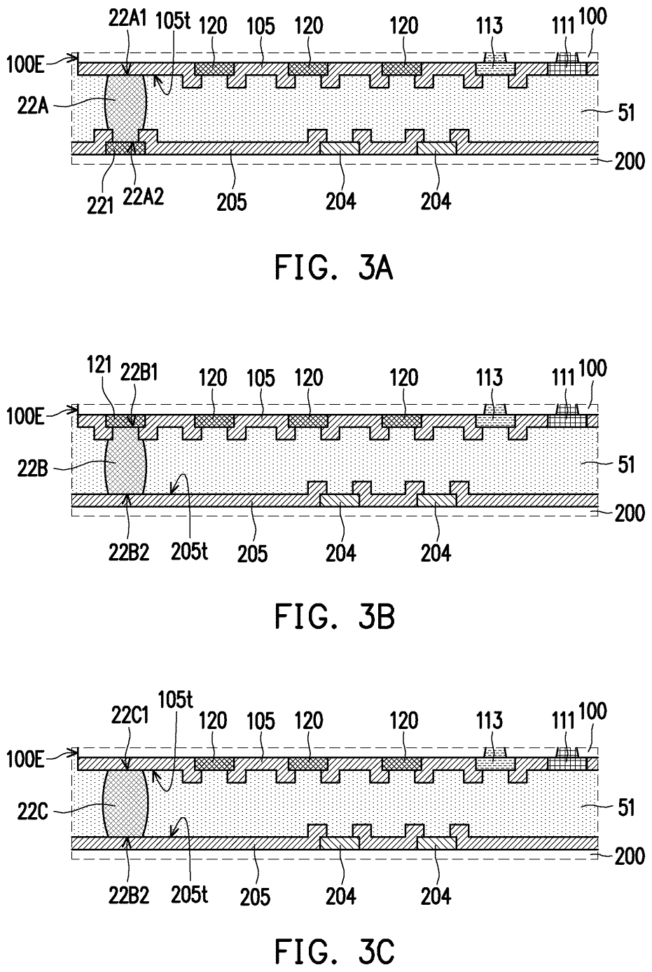

With continued reference to FIGS. 2A and 1A, the interposer 200 may include dummy pads 221 and dummy bumps 222 formed on the dummy pads 221. For example, the dummy pads 221 are partially covered by the first dielectric layer 205, the openings of the first dielectric layer 205 may accessibly expose at least a portion of the dummy pads 221, and the dummy bumps 222 may extend into the openings of the first dielectric layer 205 to land on the dummy pads 221. In some embodiments, the dummy pads 221 and the dummy bumps 222 are arranged in proximate to the edge 200E of the interposer 200. The locations of the dummy bumps 222 may correspond to the locations of the dummy bumps 122 of the semiconductor die 100. It should be noted that not each of the dummy bumps of the semiconductor die corresponds to one of the dummy bumps of the interposer, vice versa, and the details thereof will be described later in accompanying with FIGS. 3A-3C.

The dummy pads 221 and the dummy bumps 222 may be electrically floating in the interposer 200. In some embodiments, the dummy pads 221 are directly formed on the first side 201a of the semiconductor substrate 201. In some embodiments where the interconnect structure is formed between the semiconductor substrate 201 and the first dielectric layer 205, the dummy pads 221 are directly formed on the top of the interconnect dielectric layer. In some embodiments, no conductive feature is formed directly below the dummy pads 221. The dummy pads 221 and the dummy bumps 222 may be respectively similar to the dummy pads 121 and the dummy bumps 122 described above with reference to FIG. 1A, and the description is not repeated herein.

Referring to FIG. 2B and with reference to FIG. 2A, the semiconductor die 100 may be coupled to the interposer 200. It should be noted that although FIG. 2B shows that a single semiconductor die 100 is bonded to the interposer 200, more than one semiconductor dies may be coupled to the interposer 200 according to some embodiments. For example, the semiconductor die 100 is first aligned with the interposer 200, where the conductive bumps 106 of the semiconductor die 100 are in contact with the first conductive bumps 206, and the dummy bumps 122 of the semiconductor die 100 are in contact with the dummy bumps 222. One or more reflow operation(s) may be performed to reflow the bumps to form the first conductive (or active) joints 66 and dummy joints (e.g., second joints) 22, respectively. For example, thermal operations are performed to melt solder material and produce generally round solder joints, some of which in the first region are coupled to the contact pads (104 and 204) and the other in the second region are coupled to the dummy pads (121 and 221).

In some embodiments, a first underfill 51 is formed between the semiconductor die 100 and the interposer 200 to surround the first conductive joints 66 and the dummy joints 22. The first underfill 51 may be formed by a capillary flow process after the semiconductor die 100 is attached to the interposer 200 or may be formed by a suitable deposition method before the semiconductor die 100 is attached. In some embodiments, the first underfill 51 extends upward to cover at least a lower portion of the die edge 100E. In some embodiments, the first underfill 51 is in direct contact with the outer surfaces of the passivation layer 105 of the semiconductor die 100 and the first dielectric layer 205 of the interposer 200. The first underfill 51 may extend into the openings of the passivation layer 105 and the first dielectric layer 205 to be in direct contact with the surfaces of the contact pads and the dummy pads (e.g., 120 and 204) that were accessibly exposed before the formation of the first underfill 51. In some embodiments, the first underfill 51 is in direct contact with the surfaces (e.g., 111t and 113t) of the seal ring structure 111 and the test line structure 113 that were accessibly exposed before the formation of the first underfill 51.

The dummy joints 22 formed at the peripheral region of the semiconductor die 100 may anchor the first underfill 51, which may thereby protect the first underfill 51 at the die edge 100E from cracking/delamination, and which may also provide improved stress relief, without having a significant impact on manufacture processes, time and costs. Since the passivation layer 105 of the semiconductor die 100 has a roughened topography by forming the openings (e.g., 105p labeled in FIG. 1A) of the passivation layer 105 revealing the first dummy pads 120, the adhesion between the first underfill 51 and the semiconductor die 100 at the peripheral region of the die may be enhanced, thereby preventing cracks from reaching the first region of the semiconductor die 100. The first dummy pad 120, the dummy joints 22, and/or the dummy pads (121 and 221) coupled to the dummy joints 22 may be respectively or collectively viewed as a dummy pad structure. It is appreciated that stress induced defects such as cracks and delamination are likely to occur near die corners where susceptibility to die failure from such defects is highest. The dummy pad structure may protect the semiconductor die 100 against potential damage caused by stress induced defects.

Referring to FIG. 2C and with reference to FIG. 2B, an insulating encapsulant 52 may be formed on the interposer 200 to cover the semiconductor die 100 and the first underfill 51. The insulating encapsulant 52 may be molding compound, molding underfill, epoxy resin, or the like, and may be applied by compression molding, transfer molding, or the like. In some embodiments, the insulating encapsulant 52 is formed by: forming a layer of encapsulating material on the interposer 200 to bury the semiconductor die 100 and the first underfill 51, curing the encapsulating material, and optionally performing a planarization process (e.g., chemical mechanical polishing (CMP), grinding, etching, a combination thereof, etc.) on the encapsulating material to level the encapsulating material with the semiconductor die 100. For example, a surface 52t of the insulating encapsulant 52 is substantially leveled (or coplanar) with a rear surface 100t of the semiconductor die 100, within process variations. Alternatively, the insulating encapsulant 52 is omitted.

In some embodiments, second contact pads 206 are formed on a second side 201b of the semiconductor substrate 201 and electrically coupled to the TSVs 203, where the second side 201b is opposite to the first side 201a. In some embodiments, a planarization process (e.g., CMP, grinding, etching, a combination thereof, etc.) is performed on the semiconductor substrate 201 to expose the TSVs 203 before forming the second contact pads 206. In some embodiments, an interconnect structure (not shown) is formed on the second side 201b of the semiconductor substrate 201 and interposed between the second contact pads 206 and the TSVs 203. In some embodiments, a second dielectric layer 207 is formed on the second side 201b of the semiconductor substrate 201 and partially covers the second contact pads 206. In some embodiments, second conductive bumps (or second active bumps) 208 are formed on the second contact pads 206. The dimension of the respective second conductive bump 208 may be greater than that of the respective first conductive bump 206. The second conductive bumps 208 may be BGA connectors, solder balls, metal pillars, C4 bumps, micro bumps, ENEPIG formed bumps, or the like. In some embodiments, a singulation process is performed to cut off the insulating encapsulant 52 (if exist) and the interposer 200, and the resulting structure may be viewed as a chip-on-wafer (CoW) package 10′.

Referring to FIG. 2D and with reference to FIG. 2C, the structure shown in FIG. 2C is optionally bonded to a circuit substrate 300 through the second conductive bumps 208. The circuit substrate 300 may be any suitable package substrate, such as a printed circuit board (PCB), an organic substrate, a ceramic substrate, a motherboard, or the like. The circuit substrate 300 may be used to interconnect CoW package 10′ with other packages/devices to form functional circuits. The circuit substrate 300 has a first side 300a bonded to the CoW package 10′ and a second side 300b opposite to the first side 300a. In some embodiments, the circuit substrate 300 includes contact pads 302 formed on the first side 300a and may (or may not) include conductive terminals 304 formed on the second side 300b. The conductive terminals 304 may be BGA connectors, solder balls, metal pillars, C4 bumps, micro bumps, ENEPIG formed bumps, or the like. The dimension of the respective conductive terminal 304 may be greater than that of the respective second conductive bump 208.

In some embodiments, the second conductive bumps 208 of the CoW package 10′ are placed on the contact pads 302, and a reflow process may be performed to reflow the second conductive bumps 208, thereby forming second conductive joints (e.g., solder joints) 88 coupling the second contact pads 206 of the interposer 200 to the contact pads 302 of the circuit substrate 300. In some embodiments, a second underfill 53 is formed in a gap between the circuit substrate 300 and the interposer 200 to surround the second conductive joints 88. In some embodiments, the second underfill 53 extends upward to cover at least a lower portion of the edge 200E of the interposer 200. Alternatively, the second underfill 53 is omitted. The structure shown in FIG. 2D may be a semiconductor package 10 which can be viewed as a three-dimensional integrated circuit (3DIC) package or a chip-on-wafer-on-substrate (CoWoS) package. The CoWoS package can be used in a variety of applications including AI, machine learning, 5G networking, etc. The conductive terminals 304 of the semiconductor package 10 may be used to electrically connect the semiconductor package 10 to a motherboard (not shown) or another device component of an electrical system.

FIGS. 3A through 3C illustrate schematic enlarged views of some other embodiments of the structure in the dashed box B outlined in FIG. 2D. Unless specified otherwise, the materials and the formation methods of the components in these embodiments are essentially the same as the like components, which are denoted by like reference numerals in the embodiments shown in FIGS. 1A through 2D.

Referring to FIG. 3A and FIG. 2D, the different between the structure shown in FIG. 3A and the structure outlined in the dashed box B of FIG. 2D includes that the dummy joint 22A has one end directly landing on the passivation layer 105 of the semiconductor die 100. For example, the dummy joint 22A has a first end 22A1 directly coupled to the outer surface 105t of the passivation layer 105 of the semiconductor die 100 and a second end 22A2 opposite to the first end 22A1 and directly landing on the dummy pad 221 of the interposer 200. The substantial entirety of the surface of the first end 22A1 may be in physical contact to the passivation layer 105. The second end 22A2 of the dummy joint 22A may pass through the opening of the first dielectric layer 205 to land on the dummy pad 221 such that the dummy joint 22A may be in direct contact with the inner sidewalls of the first dielectric layer 205 and the top surface of the first dielectric layer 205. The area of the first end 22A1 directly connected to the passivation layer 105 may be greater than the area of the second end 22A2 directly connected to the dummy pad 221. In some embodiments, the dummy joint 22A is the one of the dummy joints which is most proximate to the die edge 100E.

Referring to FIG. 3B and with reference to FIG. 3A, the different between the structure shown in FIG. 3B and the structure shown in FIG. 3A includes that the dummy joint 22B has one end directly landing on the first dielectric layer 205 of the interposer 200. For example, the dummy joint 22B has a first end 22B1 directly landing on the second dummy pad 121 of the semiconductor die 100 and a second end 22B2 opposite to the first end 22B1 directly coupled to the outer surface 205t of the first dielectric layer 205 of the interposer 200. The substantial entirety of the surface of the second end 22B2 may be in physical contact to the first dielectric layer 205. The area of the second end 22B2 directly connected to the first dielectric layer 205 may be greater than the area of the first end 22B1 directly connected to the second dummy pad 121. In some embodiments, the dummy joint 22B is the one of the dummy joints which is most proximate to the die edge 100E.

Referring to FIG. 3C and with reference to FIG. 3A, the different between the structure shown in FIG. 3C and the structure shown in FIG. 3A includes that the dummy joint 22C has the opposing ends directly landing on the first dielectric layer 205 of the interposer 200 and the passivation layer 105 of the semiconductor die 100, respectively. For example, the dummy joint 22C has a first end 22C1 directly coupled to the outer surface 105t of the passivation layer 105 and a second end 22C2 opposite to the first end 22C1 directly coupled to the outer surface 205t of the first dielectric layer 205. The substantial entirety of the surface of the first end 22C1 may be in physical contact to the passivation layer 105, and the substantial entirety of the surface of the second end 22C2 may be in physical contact to the first dielectric layer 205. The area of the second end 22C2 may be substantially equal to the area of the first end 22C1. In some embodiments, the dummy joint 22C is the one of the dummy joints which is most proximate to the die edge 100E.

The semiconductor die 100 may include any combination of the dummy joints (e.g., 22, 22A, 22B, and/or 22C) arranged in the peripheral region of the semiconductor die 100. By configuring the dummy joints at the die corners, the resulting structure anchoring the first underfill 51 may provide more relief of the stress that accumulates during thermal cycling and die separation. That is, the dummy joints (e.g., 22, 22A, 22B, and/or 22C) may anchor the first underfill 51, which may thereby protect the first underfill 51 at the die edge 100E from cracking/delamination, and which may also provide improved stress relief, without having a significant impact on manufacture processes, time and costs. The embodiments presented herein allow for reducing or eliminating the generation of defects (e.g., cracks and/or delamination) in the semiconductor package 10 (especially around the die corners), and improving the reliability of the semiconductor package 10.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor package includes a semiconductor die, an interposer disposed below the semiconductor die, first joints electrically coupling the semiconductor die to the interposer, at least one dummy joint coupling the semiconductor die to the interposer, and a first underfill disposed between the semiconductor die and the interposer to surround the active and dummy joints. The semiconductor die includes a first region, a seal ring region surrounding the first region, and a second region between the seal ring region and a die edge. The first joints are located within the first region, and the dummy joint is disposed at a die corner within the second region and is electrically floating in the semiconductor package.

According to some alternative embodiments, a semiconductor package includes a first package component, a second package component disposed below the first package component, dummy joints, and an underfill disposed between the first and second package components. The first package component includes active pads and a dummy pad structure, the dummy pad structure includes first dummy pads disposed at a die corner and second dummy pads disposed alongside the first dummy pads and between the active pads and a die edge. The second package component is electrically coupled to the first package component through first joints coupled to the active pads. The dummy joints are coupled to the first dummy pads and anchor the second package component. The underfill laterally covers the first joints and the dummy joints and is in contact with at least a portion of the second dummy pads.

According to some alternative embodiments, a manufacturing method of a semiconductor package includes: providing a semiconductor die and an interposer, respectively, wherein semiconductor die comprises active bumps in a first region, a seal ring structure in a seal ring region surrounding the first region, and dummy bumps in a second region between the seal ring region and a die edge; coupling the semiconductor die to the interposer by reflowing the active bumps and the dummy bumps to form first joints and dummy joints, respectively, wherein the semiconductor die is electrically coupled to the interposer through the first joints, and the dummy joints coupled to the semiconductor die and the interposer are electrically floating; and forming an underfill between the semiconductor die and the interposer to surround the first joints and the dummy joints.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor package, comprising:
providing a semiconductor die and an interposer, respectively, wherein the semiconductor die comprises active bumps in a first region, a seal ring structure in a seal ring region surrounding the first region, and dummy bumps in a second region between the seal ring region and a die corner;
coupling the semiconductor die to the interposer by reflowing the active bumps and the dummy bumps to form first joints and second joints, respectively, wherein the semiconductor die is electrically coupled to the interposer through the first joints, and the second joints coupled to the semiconductor die and the interposer are electrically floating; and
forming an underfill between the semiconductor die and the interposer to surround the first joints and the second joints.

2. The manufacturing method of claim 1, wherein providing the semiconductor die comprises:
roughening a portion of a passivation material layer by forming openings to expose first dummy pads and second dummy pads of the semiconductor die, wherein the first dummy pads are arranged within the second region and in proximity to the dummy bumps, and after forming the underfill, the underfill extends into the openings to be in contact with the first dummy pads.

3. The manufacturing method of claim 2, wherein the dummy bumps extend through the openings to land on the second dummy pads.

4. The manufacturing method of claim 1, wherein coupling the semiconductor die to the interposer comprises:
reflowing the dummy bumps of the semiconductor die to form the second joints, wherein at least one of the second joints has a substantial entirety of one end directly connected to a dielectric layer of the interposer.

5. The manufacturing method of claim 1, wherein the semiconductor die further comprises:
at least one test pad disposed within the second region and comprising a probe mark, and after forming the underfill, the underfill directly covering the probe mark.

6. The manufacturing method of claim 5, wherein the at least one test pad comprises an array of test pads arranged within the second region, the second region comprises a dummy area other than a distributed area of the array of test pads, and the dummy area comprises a forbidden zone in which the second joints are located.

7. A manufacturing method of a semiconductor package, comprising:
providing a semiconductor die, wherein the semiconductor die comprises an active region and an inactive region surrounding the active region, and comprises dummy bumps at a die corner in the inactive region;
coupling the semiconductor die to an interposer by reflowing the dummy bumps to form joints, wherein the joints coupled to the semiconductor die and the interposer are electrically floating; and
forming an underfill between the semiconductor die and the interposer to surround the joints.

8. The manufacturing method of claim 7, wherein providing the semiconductor die comprises:
roughening a portion of a passivation material layer by forming openings to expose at least a portion of dummy pads of the semiconductor die, wherein the dummy pads are arranged within the second region and in proximity to the dummy bumps, and after forming the underfill, the underfill extends into the openings to be in contact with the portion of dummy pads.

9. The manufacturing method of claim 7, wherein the semiconductor die further comprises:
at least one test pad disposed within the inactive region and comprising a probe mark, and after forming the underfill, the underfill directly covering the probe mark.

10. The manufacturing method of claim 9, wherein the at least one test pad comprises an array of test pads arranged within the second region, the second region comprises a dummy area other than a distributed area of the array of test pads, and the dummy area comprises a forbidden zone in which the joints are located at the die corner.

11. The manufacturing method of claim 10, wherein the semiconductor die further comprises:
an array of dummy pads arranged in the dummy area other than the forbidden zone, wherein a distribution area of the array of dummy pads in the dummy area is greater than an area of the joints in the dummy area.

12. The manufacturing method of claim 7, wherein coupling the semiconductor die to the interposer comprises:
reflowing the dummy bumps of the semiconductor die to form the joints, wherein at least one of the joints has a substantial entirety of one end directly connected to a dielectric layer of the interposer.

13. The manufacturing method of claim 7, wherein an area of the one end of the at least one of the joints connected to the dielectric layer of the interposer is greater than an area of another end of the at least one of the joints.

14. A manufacturing method of a semiconductor package, comprising:
providing a semiconductor die, wherein the semiconductor die comprises active bumps in a first region, and dummy bumps at a die corner in a second region, the second region surrounding the first region;
coupling the semiconductor die to an interposer by reflowing the active bumps and the dummy bumps to form first joints and second joints, respectively, wherein the semiconductor die is electrically coupled to the interposer through the first joints, and the second joints coupled to the semiconductor die and the interposer are electrically floating; and
forming an underfill between the semiconductor die and the interposer to laterally cover the first joints and the second joints.

15. The manufacturing method of claim 14, wherein the semiconductor die further comprises:
first and second dummy pads arranged within the second region, wherein after coupling the semiconductor die to the interposer, the second joints land on the second dummy pads; and
a passivation layer extending across the first region and the second region, and the passivation layer partially covering the first and second dummy pads.

16. The manufacturing method of claim 15, wherein after forming the underfill, the underfill extends through the passivation layer to be in direct contact with the first dummy pads.

17. The manufacturing method of claim 15, wherein a distribution area of the first dummy pads is greater than an area of the second joints.

18. The manufacturing method of claim 17, wherein the semiconductor die further comprises:
at least one test pad disposed within the second region and comprising a probe mark, and after forming the underfill, the underfill directly covering the probe mark.

19. The manufacturing method of claim 18, wherein the at least one test pad comprises an array of test pads arranged within the second region, the second region comprises a dummy area other than a distributed area of the array of test pads, and the dummy area comprises a forbidden zone in which the second joints are located.

20. The manufacturing method of claim 19, wherein the first dummy pads are arranged in the dummy area other than the forbidden zone.
